(19) United States
(12) Patent Application Publication
(10) Pub. No.: US 2007/0114562 A1
(43) Pub. Date: May 24, 2007

(54) Red and yellow phosphor-converted LEDs for signal applications

(75) Inventors: Emil Vergilov Radkov, Euclid, OH (US); Anant Achyut Setlur, Niskayuna, NY (US); Ilona Elisabeth Hausmann, Elyria, OH (US)

Correspondence Address: Scott A. McCollister, Esq.;Fay, Sharpe, Fagan, Minnich & McKee, LLP, Seventh Floor, 1100 Superior Avenue, Cleveland, OH, 44114-2579, US

(73) Assignee: GELcore, LLC

(21) Appl. No.: 11/285,442

(22) Filed: Nov. 22, 2005

(51) Int. Cl. H01L 33/00

(52) U.S. Cl. 257/103

(57) ABSTRACT

There is provided yellow and red illumination systems, including a semiconductor light emitter, and a luminescent material. The systems have an emission falling within the respective ITE red and yellow color bins having specified color coordinates on the CIE chromaticity diagram. The luminescent material may include one or more phosphors. The illumination systems may be used as the red and yellow lights of a traffic light or an automotive display.

### BACKGROUND

The present exemplary embodiments relate to novel phosphor compositions. They find particular application in conjunction with converting LED-generated ultraviolet (UV), violet or blue radiation into yellow or red light or other colored light for use in traffic signals. It should be appreciated, however, that the invention is also applicable to the conversion of LED and other light source radiation for the production of green light for other applications, such as display lights, etc.

Light emitting diodes (LEDs) are semiconductor light emitters often used as a replacement for other light sources, such as incandescent lamps. They are particularly useful as display lights, warning lights and indicating lights or in other applications where colored light is desired. The color of light produced by an LED is dependent on the type of semiconductor material used in its manufacture.

Colored semiconductor light emitting devices, including light emitting diodes and lasers (both are generally referred to herein as LEDs), have been produced from Group III-V alloys such as gallium nitride (GaN). To form the LEDs, layers of the alloys are typically deposited epitaxially on a substrate, such as silicon carbide or sapphire, and may be doped with a variety of n and p type dopants to improve properties, such as light emission efficiency. With reference to the GaN-based LEDs, light is generally emitted in the UV and/or blue range of the electromagnetic spectrum.

By interposing a phosphor excited by the radiation generated by the LED, light of a different wavelength, e.g., in the visible range of the spectrum, may be generated. Colored LEDs are used in a number of commercial applications such as toys, indicator lights, automotive, display, safety/emergency, directed area lighting and other devices. Manufacturers are continuously looking for new colored phosphors for use in such LEDs to produce custom colors and higher luminosity.

One important application of semiconductor LEDs is as a light source in a traffic light. Presently, a plurality of blue-green emitting LEDs containing III-V semiconductor layers, such as GaN, etc., are used as the green light of a traffic signal (i.e. traffic lights).

Industry regulations often require traffic light colors to have very specific CIE color coordinates. For example, according to the Institute of Transportation Engineers (ITE), a yellow traffic light in the United States is typically required to have emission CIE color coordinates located within an area of a quadrilateral on the 1931 CIE chromaticity diagram, whose corners have the following color coordinates:
a) x=0.545 and y=0.454;
b) x=0.536 and y=0.449;
c) x=0.578 and y=0.408; and
d) x=0.588 and y=0.411.

Similarly, a red traffic light in the United States is typically required to have emission CIE color coordinates located within an area of a quadrilateral on the CIE chromaticity diagram, whose corners have the following color coordinates:
a) x=0.692 and y=0.308;
b) x=0.681 and y=0.308;
c) x=0.700 and y=0.290; and
d) x=0.710 and y=0.290.

The color coordinates (also known as the chromaticity coordinates) and the CIE chromaticity diagram are explained in detail in several text books, such as on pages 98-107 of K. H. Butler, “Fluorescent Lamp Phosphors” (The Pennsylvania State University Press 1980) and on pages 109-110 of G. Blasse et al., “Luminescent Materials” (Springer-Verlag 1994), both incorporated herein by reference.

Although the current red and yellow LEDs in signal applications using AlInGaP technology are relatively bright, they are rather sensitive to temperature variation. As their operating temperature rises, their color point shifts toward the red, which can cause them to exceed the specification limits on color point for the specific color. Additionally, their brightness decreases at higher operating temperature, which may cause the brightness of the LED to fall below the required specification and inhibit a motorists ability to see the signal.

Thus, a need exists for safer and more color stable colored LEDs for use in traffic signal and automotive applications. The present invention is directed to overcoming or at least reducing the problems set forth above through the use of InGaN LED chips along with certain phosphors and phosphor blends.

### BRIEF DESCRIPTION

In accordance with one aspect of the present exemplary embodiment, there is provided a yellow emitting LED illumination system including an InGaN semiconductor light emitter having a peak emission from 250 to 500 nm and a luminescent material, wherein the illumination system has an emission having CIE color coordinates located within an area of the CIE 1931 x,y chromaticity diagram bounded by the following CIE color coordinates:
a) x=0.545 and y=0.454;
b) x=0.536 and y=0.449;
c) x=0.578 and y=0.408; and
d) x=0.588 and y=0.411.

In accordance with a second aspect of the present exemplary embodiments, there is provided a red emitting LED illumination system including an InGaN semiconductor light emitter having a peak emission from 250 to 500 nm and a luminescent material, wherein the illumination system has an emission having CIE color coordinates located within an area of the CIE 1931 x,y chromaticity diagram bounded by the following CIE color coordinates:
a) x=0.692 and y=0.308;
b) x=0.681 and y=0.308;
c) x=0.700 and y=0.290; and
d) x=0.710 and y=0.290.

### BRIEF DESCRIPTION OF THE DRAWINGS

The described embodiments may take form in various components and arrangements of components, and in various process operations and arrangements of process operations. The drawings are only for purposes of illustrating preferred embodiments and are not to be construed as limiting the invention.

FIG. 1 shows a perspective view of a lighting component or package.

FIG. 2 shows a perspective view of the printed circuit board of the lighting package of FIG. 1 with the light emitting dice or chips and associated electrical components disposed thereon.

FIG. 3 shows a perspective view of the lighting component or package of FIG. 1 with a portion of the phosphor containing light transmissive cover removed to show internal elements of the lighting package.

FIG. 4 shows a perspective view of yet another lighting component or package, in which the light emitting dice and the phosphor are encapsulated by separate encapsulants. In FIG. 4, a portion of the phosphor containing light transmissive cover removed to show internal elements of the lighting package.

FIG. 5 shows a perspective view of still yet another lighting component or package, in which the printed circuit board includes two evaporated conductive traces. In FIG. 5, a portion of the phosphor containing light transmissive cover removed to show internal elements of the lighting package.

FIG. 6 shows a graph of the CIE color coordinates for various light emitting structures with different phosphor blends according to the present embodiments.

### DETAILED DESCRIPTION

Phosphors convert radiation (energy) to visible light. Different combinations of phosphors provide different colored light emissions. The colored light that originates from the phosphors provides a color temperature. Novel phosphor compositions are presented herein as well as their use in LED and other light sources.

A phosphor conversion material (phosphor material) converts generated UV or blue radiation to a different wavelength visible light. The color of the generated visible light is dependent on the particular components of the phosphor material. The phosphor material may include only a single phosphor composition or two or more phosphors of basic color, for example a particular mix with one or more of a yellow and red phosphor to emit a desired color (tint) of light. As used herein, the term “phosphor material” is intended to include both a single phosphor compound as well as a blend of two or more phosphor compounds.

It was determined that an LED lamp that produces red or yellow light having color properties suitable for signal applications would be useful. Therefore, in one embodiment, phosphor-converted red and yellow emitting LED based lighting package. The phosphor material may be an individual phosphor or a phosphor blend of two or more phosphor compositions, including individual phosphors that convert radiation at a specified wavelength, for example radiation from about 250 to 500 nm as emitted by a UV to blue LED, into a different wavelength visible light. The visible light provided by the phosphor material (after filtration of the bleed from the LED chip if emitting visible light, as needed) comprises a red or yellow light suitable for traffic applications.

As detailed above, the use of a phosphor converted LED lamp in the present embodiments shows improved color point stability over a range of operating temperatures compared to conventional red and yellow LED signal lamps using AlInGaP chip technology.

Although not intended to be limiting, preferred embodiments include where the phosphor is coated remotely from the chip (i.e. not directly on top of the LED chip). Suitable arrangement may be found in commonly assigned U.S. patent application Ser. No. 10/831,862, filed Apr. 26, 2004.

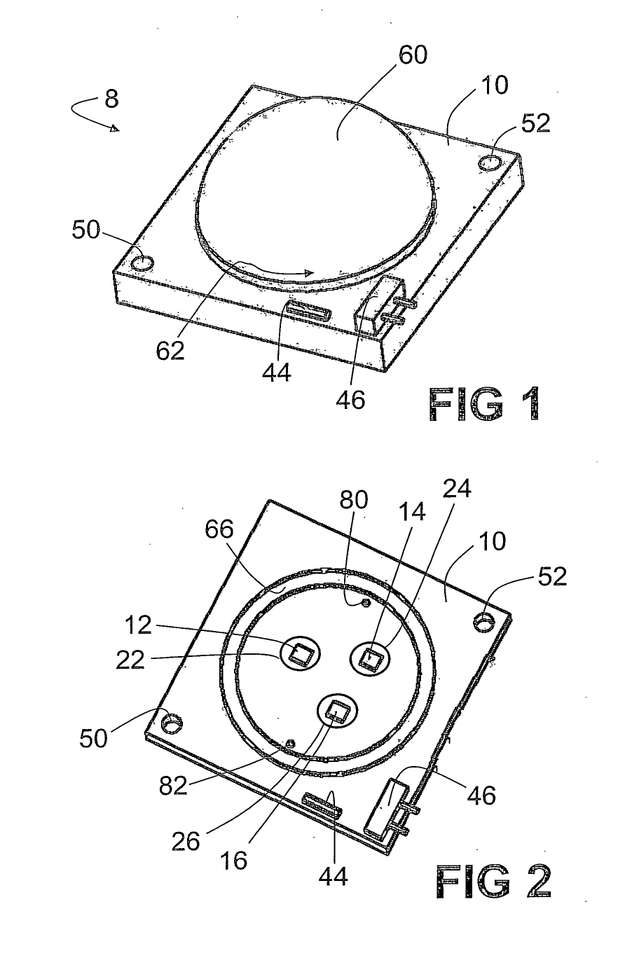

Thus, in one embodiment, and with reference to FIGS. 1-3, a light emitting package 8 includes a printed circuit board 10 on which one or more light emitting chips or die are disposed. The printed circuit board is preferably substantially thermally conductive. For example, a metal core printed circuit board can be employed. In the illustrated embodiment, three light emitting chips or dice 12, 14, 16 are disposed on the circuit board 10; however, the number of dice can be one die, two dice, or more than three dice.

The die or dice can be group III-nitride blue or ultraviolet light emitting diodes. Preferably, the die or dice is an InGaN chip having a peak emission in the range from 250-500 nm represented by the formula InᵢGaⱼN (where 0<i; 0<j; and i+j=1). In one preferred embodiment, however, the emission of the LED will be in the near UV to deep blue region and have a peak wavelength in the range from about 380 to about 430 nm. The use of InGaN chips provides better thermal stability compared to AlInGaP chips, as discussed above.

Each light emitting die or dice can be a bare die, or each die or dice can include an individual encapsulant. Still further, the die or dice can be a monolithic array of light emitting diode mesas, vertical cavity surface emitting laser mesas, or the like. In the illustrated embodiment, the dice 12, 14, 16 are disposed in corresponding reflective wells 22, 24, 26; however, the die or dice may be mounted on a planar surface of the printed circuit board 10 or can be mounted on raised pedestals or other elevated support structures. In some embodiments, a portion or all of the side of the printed circuit board 10 on which the light emitting dice or chips 12, 14, 16 are disposed has a reflective layer disposed thereon to improve light extraction from the package 8.

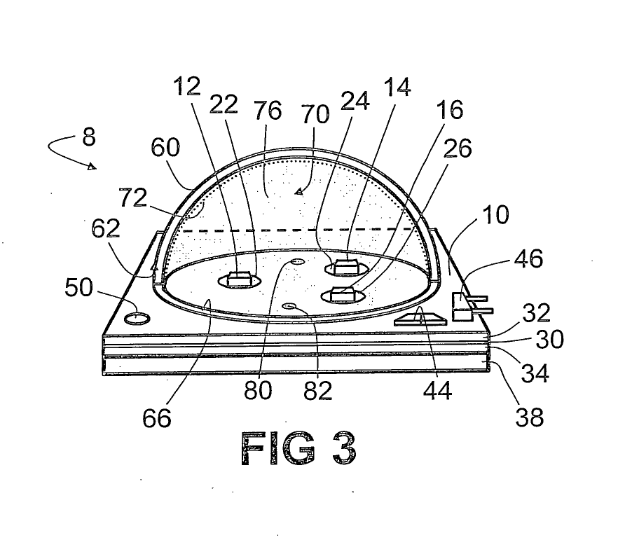

With particular reference to FIG. 3, the illustrated printed circuit board 10 includes one or more printed circuitry layers 30 sandwiched between insulating layers 32, 34. Typically, electrical pads are formed on the die attach surface of the printed circuit board 10 using appropriate vias passing through the insulating layer 32 to electrically connect the dice 12, 14, 16 with the printed circuitry 30. The die or dice 12, 14, 16 can be mechanically and electrically attached to the printed circuit board 10 in various ways, such as: by flip-chip bonding of die electrodes to electrical pads of the printed circuit board 10; by soldering the die to the board 10 and using wire bonds to electrically connect the die electrodes with electrical pads of the printed circuit board 10; by soldering the die to a lead frame (not shown) that is in turn mounted to the printed circuit board 10; or so forth.

The die attachment can include a sub-mount (not shown) disposed between a light emitting die or chip and the printed circuit board or other support, or between the chip and a lead frame. Still further, rather than mounting individual dice as illustrated herein, it is contemplated to employ a monolithic light emitting diode array formed on a common substrate. In this contemplated embodiment, the common substrate is soldered or otherwise secured to the printed circuit board 10, and electrical connection to the individual light emitting mesas or structures is made by wire bonding, conductive traces formed on the common substrate, or the like. Alternatively, a monolithic array having a transparent common substrate can be configured for a flip-chip mounting in which the electrodes of the light emitting mesas or structures are directly bonded to electrical pads.

The printed circuit board 10 may further include a heat sinking structure such as a ground plate or metal core 38 to provide heat sinking of the light emitting chips or dice 12, 14, 16. Optionally, an electrically insulating back-plate (not shown) is disposed on the side of the metal core 38 distal from the die attach surface. The heat sink is optionally omitted in lower power lighting packages, packages mounted on a heat sinking surface, or the like. Moreover, the printed circuitry layer or layers 30 may provide adequate heat sinking in some embodiments. In still yet other embodiments, the material or materials forming the insulating layers 32, 34 are chosen to be thermally conductive so that these layers provide heat sinking.

The printed circuit board 10 optionally supports associated electrical components, such as a zener diode component 44 including one or more zener diodes connected across the light emitting dice 12, 14, 16 by the printed circuitry 30 to provide electrostatic discharge protection for the dice. Similarly, electrical power conversion circuitry, power regulating circuitry, rectifying circuitry, or the like, can be included as additional components on the printed circuit board 10. Such components can be provided as one or more discrete components, or as an application-specific integrated circuit (ASIC). Moreover, an electrical plug, adaptor, electrical terminals 46, or the like can be disposed on the printed circuit board 10. In some embodiments, it is contemplated to include more than one set of electrical terminals, for example to enable series, parallel, or series-parallel interconnection of a plurality of light emitting packages. The printed circuitry 30 includes traces connecting the electrical terminals 46 with the light emitting dice or chips 12, 14, 16 such that suitable electrical power applied to the electrical terminals 46 energizes the light emitting dice or chips 12, 14, 16 and associated circuitry (if any) such as the zener diode component 44. The printed circuit board 10 can include other features such as a mounting socket, mounting openings 50, 52 or the like for mechanically installing or securing the light emitting package 8.

The described printed circuit board 10 is an example. Other types of printed circuit boards or other support structures can also be employed. For example, the printed circuit traces can be disposed on the die attach surface and/or on the bottom surface rather than being sandwiched between insulating layers 32, 34. Thus, for example, the printed circuit board can be an electrically insulating support with a conductive trace evaporated and patterned or otherwise formed on the insulating support. Moreover, a heat sink can be substituted for the printed circuit board, for example with the light emitting die or dice soldered or otherwise mechanically secured to the heat sink and with the die electrodes wire bonded to electrical pads.

With continuing reference to FIGS. 1-3, the light emitting package 8 further includes a light transmissive cover 60 disposed over the light emitting dice or chips 12, 14, 16. The light transmissive cover has an open end defining a cover perimeter 62 that connects with the printed circuit board 10. In the illustrated embodiment, the printed circuit board 10 includes an optional annular groove 66 that receives the perimeter 62 of the light transmissive cover 60, which in the light emitting package 8 is a hemispherical dome-shaped cover. The groove 66 guides in positioning the cover 60 on the printed circuit board 10, and optionally also is used to help secure the cover to the board. In some embodiments the annular groove 66 is omitted, in which case the placement of the cover 60 on the printed circuit board 10 is positioned by other means, such as by using an automated assembly jig.

The light transmissive cover 60 can be secured to the printed circuit board 10 in various ways, such as by an adhesive, by a friction fit between the perimeter 62 and the groove 66, by fasteners, or so forth. The light transmissive cover 60 together with the printed circuit board 10 define an interior volume 70 containing the light emitting dice or chips 12, 14, 16. In some embodiments, the connection between the perimeter 62 of the light transmissive cover 60 and the printed circuit board 10 is a substantially airtight sealing connection that substantially hermetically seals the interior volume 70. In other embodiments, the connection between the perimeter 62 and the printed circuit board 10 is not a hermetic seal, but rather may contain one or more gaps, openings, or the like.

A phosphor 72 (indicated by a dotted line in FIG. 3) is coated or otherwise deposited on an inside surface of the cover 60. The phosphor is selected to produce a desired wavelength conversion of a portion or substantially all of the light produced by the light emitting dice or chips 12, 14, 16. The term “phosphor” is to be understood as including a single phosphor compound or blends of two or more chemically distinct individual compounds chosen to produce a selected wavelength conversion. Examples of suitable phosphor compounds are described below. In one embodiment, the light emitting dice or chips 12, 14, 16 are blue, violet, or ultraviolet emitting diodes, and the phosphor 72 is a red or yellow phosphor that converts most or substantially all of the light generated by the chips 12, 14, 16 into yellow or red light having specific characteristics.

In some embodiments, the light transmissive cover 60 is a glass cover, where “glass” is not limited to silica-based materials but rather encompasses substantially any inorganic, amorphous light transmissive material. Making the cover 60 of glass has certain advantages over plastic or other organic covers. Glass typically has better thermal stability than most plastics. Glass is more readily coated with optical coatings such as wavelength-selective reflective coatings, wavelength-selective absorbing coatings, or the like. Glass is also typically more resistant to scratching compared with most plastics. Moreover, glass has particular advantages in embodiments in which the light emitting dice or chips 12, 14, 16 produce ultraviolet or short-wavelength visible light, because light at these wavelengths can discolor or otherwise degrade the optical quality of light transmissive plastics over time. In other embodiments, the light transmissive cover 60 is made of plastic or another organic light transmissive material. In yet other contemplated embodiments, the cover 60 is made of a crystalline light transmissive material such as crystalline quartz. Such crystalline covers typically share many of the advantages of glass covers.

Moreover, the printed circuit board 10 can include various reflective coatings or reflective surfaces for improving light extraction efficiency. In some embodiments, substantially the entire surface of the printed circuit board on which the light emitting dice or chips 12, 14, 16 and the cover 60 are disposed is reflective for both light produced by the light emitting chips and for light produced by the phosphor 72. In other embodiments, that portion or area of the printed circuit board surface covered by the cover 60 is reflective for both light produced by the light emitting chips and for light produced by the phosphor 72, while that portion or area of the printed circuit board surface outside of the cover 60 is reflective principally for light produced by the phosphor 72. These latter embodiments are suitable when substantially all of the direct light produced by the light emitting dice or chips 12, 14, 16 is converted by the phosphor, so that the output light is substantially entirely due to the phosphor. By using different reflective coatings or surfaces inside of and outside of the cover 60, each reflective coating or surface can be independently optimized for the spectrum of light which it is intended to reflect.

It will be appreciated that the term “light transmissive” as used herein to describe the cover 60 refers to the desired light output produced by the light emitting package 8. The light output includes light generated by the phosphor 72, if present, responsive to irradiation by the light emitting dice or chips 12, 14, 16. In some embodiments, the light output includes a portion or all of the direct light produced by the light emitting dice or chips 12, 14, 16. Examples of the latter embodiments are a white light in which the white output light is a blending of blue light emitted by the light emitting dice or chips 12, 14, 16 and yellow light emitted by the phosphor 72, or embodiments in which the phosphor 72 is omitted entirely. Where the direct light produced by the light emitting dice or chips 12, 14, 16 contributes to the output light, the cover 60 should be at least partially light transmissive for that direct light. In embodiments where the output light is solely produced by the phosphor 72, on the other hand, the cover 60 may be light transmissive for the phosphor output but partially or wholly reflective or absorbing for the direct light produced by the light emitting dice or chips 12, 14, 16. An example of such a light emitting package is a white light emitting package in which the output white light is produced by the phosphor 72 responsive to violet or ultraviolet light produced by the light emitting dice or chips 12, 14, 16.

The phosphor 72 can be applied to the inside surface of the light transmissive cover 60 using a suitable phosphor coating process, such as for example, electrostatic coating, slurry coating, spray coating, or so forth. Moreover, the phosphor can be deposited elsewhere besides on the inside surface of the cover 60. For example, the phosphor can be applied to the outside surface of the cover 60, using for example spray coating, outer surface coating, or the like, or to both the inside and outside surfaces of the cover 60. In yet another embodiment, the phosphor is embedded in the material of the light transmissive cover 60. However, phosphor is not readily embedded into most glass or crystalline materials. In some embodiments the phosphor is dispersed in a glass binder that is spun onto or otherwise coated onto the inside and/or outside surface of the cover 60.

In one suitable process, the inside surface of the cover 60 is prepared by treatment with a liquid or low viscosity semi-solid material acting as a glue. The liquid material can be, for example, liquid epoxy or silicone. The glue material can be applied in a variety of ways, such as by spraying, brushing, or dipping of its working formulation or a solution thereof in a suitable solvent such as acetone or methyl isobutyl ketone (MIBK) or t-butyl acetate or n-butyl acetate. The phosphor is then deposited by dusting, dipping or pouring of phosphor in powder form, the choice of deposition method being based on the nature of the inside surface of the cover 60. For example, pour phosphor powder is suitably poured into the concave inside surface of the cover 60. On the other hand, dipping is generally a better method for coating the outside surface of the cover 60. The glue is then hardened by solvent evaporation, thermal or UV curing, or the like to form the phosphor layer.

Repetitions or various combinations of the above-described example phosphor deposition and hardening processes may be performed, for example to deposit more than one phosphor or a blend of phosphors, or as needed to attain a required thickness or layered structure. Optionally, the phosphor coating may be covered with a final layer of clear glue or other suitable material to provide mechanical protection, to filter out ambient ultraviolet light or excess radiation from the light emitting dice 12, 14, 16, or so forth.

The light transmissive cover 60 optionally includes one or more optical coatings besides the phosphor 72. In some embodiments, an anti-reflective coating is applied to the inside and/or outside surface of the cover 60 to promote light transmission. In embodiments in which the direct light produced by the light emitting dice or chips 12, 14, 16 does not form part of the output light, the light transmissive cover 60 optionally includes a wavelength-selective reflective coating to reflect the direct light back into the interior volume 70 where it has additional opportunity to interact with the phosphor 72.

In preferred embodiments, the light transmissive cover 60 is a single piece cover, such as a single piece glass cover, a single piece molded plastic cover, or the like. Manufacturing the cover 60 as a single piece simplifies assembly of the lighting package 8. Another advantage of a single piece cover 60 is that a substantially hermetic sealing of the interior volume 70 is obtained by ensuring a substantially hermetic seal between the perimeter 62 of the cover 60 and the printed circuit board 10. The light transmissive cover 60 can include facets, Fresnel lens contours, or other light refractive features that promote light scattering to produce a more spatially uniform light output. Similarly, the light transmissive cover 60 can be made of a frosted glass that has been etched with sand or the like to produce light scattering.

With particular reference to FIG. 3, the interior volume 70 is, in the lighting package 8, substantially filled with an encapsulant 76. The encapsulant 76 can be, for example, a silicone encapsulant, an epoxy encapsulant, or the like. The encapsulant 76 is transparent to light produced by the light emitting dice or chips 12, 14, 16 and acts as a refractive index-matching material promoting light extraction out of the light emitting dice or chips 12, 14, 16, and preferably also promoting light coupling with the phosphor 72 and, if the direct light produced by the light emitting dice 12, 14, 16 directly contributes to the package light output, also preferably promotes light transmission into the cover 60.

In some embodiments, the phosphor is dispersed in a binding material that is the same material as the encapsulant 76. In other embodiments the phosphor-binding material is a different material that has a good refractive index match with the encapsulant 76. In yet other embodiments, the encapsulant 76 serves as the binding material for the phosphor 72. It will be appreciated that while the phosphor 72 is shown in FIG. 3 as residing substantially along the inside surface of the cover 60, in some embodiments the phosphor 72 may extend some distance away from the inside surface of the cover 60 and into the encapsulant 76 disposed in the interior volume 70. In some contemplated embodiments, the phosphor is dispersed substantially into the encapsulant 76, and may even be uniformly distributed throughout the encapsulant 76. However, as described in International Publication WO 2004/021461 A2, there are efficiency advantages to spatially separating the phosphor from the light emitting dice or chips. Hence, in preferred embodiments the phosphor is disposed on the inside surface of the cover 60, or is disposed closer to the cover 60 than to the light emitting dice or chips 12, 14, 16.

In embodiments in which the light emitting dice or chips 12, 14, 16 are bare dice, that is, are not individually encapsulated, the encapsulant 76 provides a common encapsulation of the light emitting dice or chips 12, 14, 16 which protects the chips from damage due to exposure to moisture or other detrimental environmental effects. The encapsulant 76 may also provide potting of the light emitting dice or chips 12, 14, 16 to improve the robustness of the lighting package 8 and make the lighting package 8 more resistant to damage from vibrations or other mechanical disturbances.

In some embodiments the cover 60 is sealed to the printed circuit board 10, and the encapsulant 76 is injected into the interior volume 70 after the light transmissive cover is sealed. To enable encapsulant injection, openings 80, 82 are provided in the printed circuit board 10. Alternatively, openings can be provided in the light transmissive cover or at the interface between the perimeter of the cover and the printed circuit board. At least two such openings 80, 82 are preferably provided, so that while encapsulant material is injected into one opening displaced air can exit via another opening. In other embodiments, a single elongated or otherwise enlarged opening is used to provide room for both the inflowing encapsulant and the outflowing displaced air.

In embodiments in which the interior volume 70 is substantially hermetically sealed, the injected encapsulant 76 can be a liquid or non-rigid semi-solid encapsulant that is contained by the hermetically sealed interior volume 70. The liquid or non-rigid semi-solid encapsulant may be left uncured in some embodiments, since the hermetic seal prevents leakage of the encapsulant. Moreover, a hermetic seal optionally allows the encapsulant to be injected under some pressure, so that the encapsulant is at a pressure higher than atmospheric pressure. In some embodiments, the interior volume 70 is not hermetically sealed, and some of the injected encapsulant material may leak out. It will be appreciated that for encapsulant material of reasonably high viscosity, the amount of leaked encapsulant material is limited, and such leaked encapsulant material may even be advantageous insofar as it may help seal the interior volume 70 when the injected encapsulant is cured or otherwise hardened into a solid.

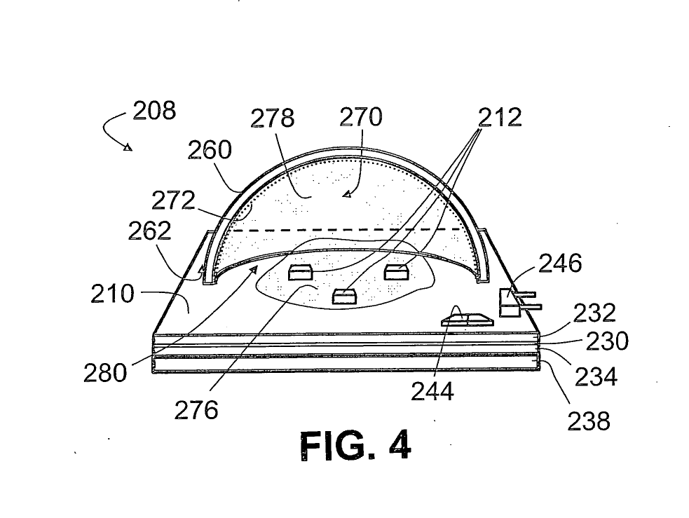

With reference to FIG. 4, yet another lighting package 208 includes a printed circuit board 210 on which one or more (specifically three in the illustrated embodiment) light emitting dice or chips 212 are arranged. In the lighting package 208, the light emitting dice or chips 212 are not disposed in reflective wells; rather, they are surface-mounted to a level surface of the printed circuit board 210. The printed circuit board 210 includes one or more printed circuitry layers 230 sandwiched between insulating layers 232, 234, and a ground plate or metal core 238. A zener diode component 244 provides electrostatic discharge protection for the light emitting dice or chips 212. Electrical terminals 246 disposed on the printed circuit board 210 deliver electrical power to the light emitting dice or chips 212 via the printed circuitry 230. A light transmissive cover 260 covers the light emitting dice or chips 212 and has an open end defining a perimeter 262 that is connected with the printed circuit board 210 to define an interior volume 270 containing the light emitting dice or chips 212. A phosphor 272 optionally coats an inside surface of the light transmissive cover 260. The above-described, elements of the lighting component or package 208 are similar to corresponding elements of the lighting component or package 8 shown in FIGS. 1-3.

The lighting package 208 differs from the lighting package 8 in the configuration of the encapsulant disposed in the interior volume. In the lighting package 208, a first encapsulant 276 encapsulates and optionally pots the light emitting dice or chips 212, but does not substantially fill the interior volume 270. In some embodiments, the first encapsulant 276 may encapsulate only the one or more light emitting dice 212. A second encapsulant 278 encapsulates the phosphor 272 if such a phosphor is included in the package 208. In some embodiments, the second encapsulant 278 is the binding material of the phosphor 270. For example, the phosphor 272 may be applied to the inside surface of the cover 260, and the encapsulant in this embodiment is the binding material of the applied phosphor. Generally, the first and second encapsulants 276, 278 can be different materials. A substantial gap 280 extends between the first and second encapsulants 276, 278. Typically, the gap 280 contains air; however, it is also contemplated to fill the gap 280 with an inert gas to reduce moisture in the lighting package 208. In yet another embodiment, the gap 280 is filled with a third encapsulant different from at least one of the first and second encapsulants 276, 278. In the lighting package 208, there is no groove in the printed circuit board 210 for receiving the perimeter 262 of the cover 260. However, such a groove similar to the groove 66 of the lighting package 8 can optionally be provided to align and optionally help secure the cover 260 to the printed circuit board 210.

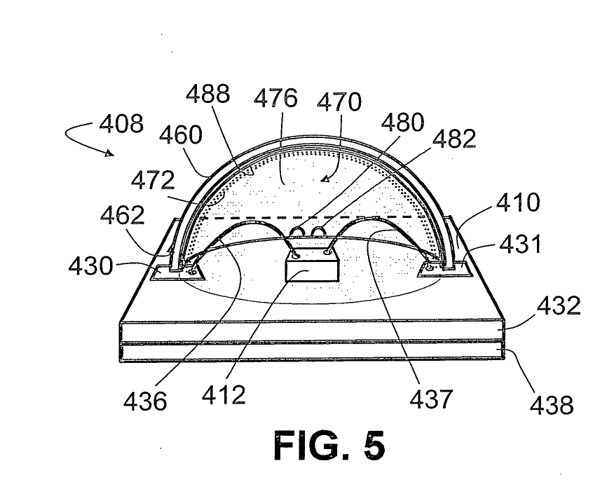

With reference to FIG. 5, still yet another lighting package 408 includes a printed circuit board 410 on which a single light emitting die or chip 412 is surface-mounted to a level surface of the printed circuit board 410. The printed circuit board 410 includes two printed circuit traces 430, 431 disposed on the same surface as the light emitting die 412. The two conductive traces 430, 431 can be formed by metal evaporation or the like. Wire bonds 436, 437 connect top-side electrodes of the light emitting die or chip 412 with the conductive traces 430, 431. The printed circuit board includes an insulating layer 432 on which the two printed circuit traces 430, 431 are formed, and an optional ground plate or metal core 438. A light transmissive cover 460 covers the light emitting die or chip 412 and has an open end defining a perimeter 462 that is connected with the printed circuit board 410 to define an interior volume 470 containing the light emitting die or chip 412. The two printed circuit traces 430, 431 extend from inside the cover 460 to outside the cover 460 to provide electrical communication into the interior volume 470. A phosphor 472 optionally coats or is otherwise deposited an inside surface of the light transmissive cover 460, and an encapsulant 476 substantially fills the interior volume 470. Hemispherical openings 480, 482 formed at the perimeter 462 of the light transmissive cover 460 allow for injection of the encapsulant material and corresponding displacement of air. That is, the openings 480, 482 of the lighting package 408 serve the same purpose as the printed circuit board openings 80, 82 of the lighting package 8 (see FIG. 3).

In any of the above structures, the lamp 10 may also include a plurality of scattering particles (not shown), which are embedded in the encapsulant material. The scattering particles may comprise, for example, Al₂O₃ particles such as alumina powder or TiO₂ particles. The scattering particles effectively scatter the coherent light emitted from the LED chip, preferably with a negligible amount of absorption.

Exemplary, but non-limiting examples of suitable yellow phosphors for use in the present embodiments include (Ca,Sr,Ba)₂Si₁₋ₐO_{4 -2a}:Eu²⁺ (wherein 0≦a≦0.2); (Mg,Ca,Sr,Ba,Zn)₅(PO₄)₃(F,Cl,Br,OH):Eu²⁺,Mn²⁺; (Mg,Ca,Sr,Ba,Zn)₂P₂O₇:Eu²⁺,Mn²⁺; Ca₃(SiO₄)Cl₂:Eu²⁺; (Y,Lu,Gd)_{2-b}Ca_{b}Si₄N_{6+b}C_{1-b}:Ce³⁺ (wherein 0≦b≦1); garnet phosphors doped with Ce³⁺; Ca_{1-c}Ce_{c}Al_{1-c}Mg_{c}SiN₃ (wherein 0.001≦c≦0.2); Ca_{1-2d}Ce_{d}Li_{d}AlSiN₃(wherein 0.001≦d≦0.2); and (Lu,Ca,Li,Mg,Y)alpha-SiAlON doped with Eu²⁺and/or Ce³⁺.

It should be noted that various phosphors are described herein in which different elements enclosed in parentheses and separated by commas, such as in the above (Ca,Sr,Ba)₂Si₁₋ₐO₄₋₂ₐ:Eu²⁺ phosphor. As understood by those skilled in the art, this type of notation means that the phosphor can include any or all of those specified elements in the formulation in any ratio. That is, this type of notation for the above phosphor, for example, has the same meaning as (Ca_{1-e-f}SrₑBa_{f})₂Si₁₋ₐO₄₋₂ₐ:Eu²⁺, wherein 0≦a≦0.2, 0≦e,f≦1.

For purposes of the present application, it should be understood that when a phosphor has two or more dopant ions (i.e. those ions following the colon in the above compositions), this is meant to mean that the phosphor has at least one (but not necessarily all) of those dopant ions within the material. That is, as understood by those skilled in the art, this type of notation means that the phosphor can include any or all of those specified ions as dopants in the formulation.

Exemplary, but non-limiting examples of suitable red phosphors for use in the present embodiments include 3.5MgO*0.5MgF₂* GeO₂:Mn^{4 +} (“MFG”), (Mg,Ca,Sr,Ba,Zn)₄Si₂O₈:Eu²+,Mn²⁺, nitride phosphors and sulfide phosphors such as (Ca,Sr,Ba_{c})₂Si₅N₈:Eu; (Ca,Sr)S:Eu; CaSiN₂:Eu and (Ba,Ca)Si₇N₁₀:Eu; L_{g}MₕN_{(2/3)g+(4/3)h)}:R or LⱼMₖOₗN_{(2/3) j+(4/3)k-(2/3)l)}:R (wherein L is at least one or more selected from the Group II Elements consisting of Mg, Ca, Sr, Ba and Zn, M is at least one or more selected from the Group IV Elements in which Si is essential among C, Si and Ge, and R is at least one or more selected from the rare earth elements in which Eu is essential among Y, La, Ce, Pr, Nd, Sm, Eu, Gd, Tb, Dy, Ho, Er and Lu.); (Ca₁₋ₘ₋ₙCeₘEuₙ)(Al₁₋ₘMgₘ)SiN₃ (wherein n>0); and (Ca_{1-o-p-q}LiₒCeₚEu_{q})Al₁₋ₒ₊ₚSi_{1+O-p}N₃ (wherein q>0).

Other suitable red phosphors include (1) A₂₋ᵣEuᵣW₁₋ₛMoₛO₆, where A is selected from Y, Gd, Lu, La, and combinations thereof; and where 0.001≦r≦0.4, 0.001≦s≦1.0; (2) MᵤOᵥX, wherein M is selected from the group consisting of Sc, Y, La, a lanthanide, Bi, an alkali earth metal and mixtures thereof; X is a halogen; 1≦u≦3; and 1≦v≦4, and having a lanthanide doping level can range from 0.001% to 40% by weight; (3) a phosphate or borate phosphor doped with Eu³⁺ selected from the group consisting of (Y,Gd,Lu,La)PO₄; (Y,Gd,Lu,La)P₃O₉; (Y,Gd,Lu,La)P₅O₁₄; (Sr,Ba,Ca)₃(Lu,Gd,Y,La)P₃O₁₂; Ca_{1.5}Ba_{1.5}(La,y,Gd,Lu)P₃O₁₂; (Y,La,Lu,Gd)BO₃; (Gd,Y,LuLa)B₃O₆; (La,Gd,Lu,Y)(Al,Ga)₃B₄O₁₂; (Y,Gd,Lu,La)MgB₅O₁₀; (Sr,Ca,Ba)(Lu,Gd,Y,La)B₇O₁₃; Ca_{0.5}Ba_{0.5}LaB₇O₁₃ or (4) A₂[MF₆]: Mn⁴⁺ where A=Li,Na, K, Rb or Cs and M=Ge, Si, Sn, Ti or Zr. An exemplary phosphor from the group (3) is Gd_{0.95}Eu_{0.05}Al₃B₄O₁₂.

Blends of the above can also be used if desired. It will be appreciated by a person skilled in the art that other phosphor compounds with sufficiently similar emission spectra may be used instead of any of the preceding suitable examples, even though the chemical formulations of such substitutes may be significantly different from the aforementioned examples.

The above described phosphor compositions may be produced using known solution or solid state reaction processes for the production of phosphors by combining, for example, elemental oxides, nitrides, carbonates and/or hydroxides as starting materials. Other starting materials may include nitrates, sulfates, acetates, citrates, or oxalates. Alternately, coprecipitates of the rare earth oxides could be used as the starting materials forthe RE elements. In a typical process, the starting materials are combined via a dry or wet blending process and fired in air or under a reducing atmosphere at from, e.g., 1000 to 1600° C.

A fluxing agent may be added to the mixture before or during the step of mixing. This fluxing agent may be NH₄Cl or any other conventional fluxing agent, such as an alkali earth fluoride. A quantity of a fluxing agent of less than about 20, preferably less than about 10, percent by weight of the total weight of the mixture is adequate for fluxing purposes.

The starting materials may be mixed together by any mechanical method including, but not limited to, stirring or blending in a high-speed blender or a ribbon blender. The starting materials may be combined and pulverized together in a bowl mill, a hammer mill, or a jet mill. The mixing may be carried out by wet milling especially when the mixture of the starting materials is to be made into a solution for subsequent precipitation. If the mixture is wet, it may be dried first before being fired under a reducing atmosphere at a temperature from about 900° C. to about 1700° C., preferably from about 1100° C. to about 1500° C., for a time sufficient to convert all of the mixture to the final composition.

The firing may be conducted in a batchwise or continuous process, preferably with a stirring or mixing action to promote good gas-solid contact. The firing time depends on the quantity of the mixture to be fired, the rate of gas conducted through the firing equipment, and the quality of the gas-solid contact in the firing equipment. Typically, a firing time up to about 10 hours is adequate but for phase formation it is desirable to refire couple of times at the desired temperatures after grinding. The reducing atmosphere typically comprises a reducing gas such as hydrogen, carbon monoxide, or a combination thereof, optionally diluted with an inert gas, such as nitrogen, helium, etc., or a combination thereof. Alternatively, the crucible containing the mixture may be packed in a second closed crucible containing high-purity carbon particles and fired in air so that the carbon particles react with the oxygen present in air, thereby, generating carbon monoxide for providing a reducing atmosphere.

These compounds may be blended and dissolved in a nitric acid solution. The strength of the acid solution is chosen to rapidly dissolve the oxygen-containing compounds and the choice is within the skill of a person skilled in the art. Ammonium hydroxide is then added in increments to the acidic solution. An organic base such as a water soluble amine may be used in place of ammonium hydroxide.

The precipitate is typically filtered, washed with deionized water, and dried. The dried precipitate is ball milled or otherwise thoroughly blended and then calcined in air at about 400° C. to about 1600° C. for a sufficient time to ensure a substantially complete dehydration of the starting material. The calcination may be carried out at a constant temperature. Alternatively, the calcination temperature may be ramped from ambient to and held at the final temperature for the duration of the calcination. The calcined material is similarly fired at 1000-1600° C. for a sufficient time under a reducing atmosphere such as H₂, CO, or a mixture of one of theses gases with an inert gas, or an atmosphere generated by a reaction between a coconut charcoal and the products of the decomposition of the starting materials or using ammonia gas to covert all of the calcined material to the desired phosphor composition.

Cutoff filters may be used if desired or needed to bring the color point of the device inside any required specification limit (e.g. ITE red or yellow bin). Such filters are known and function by cutting off radiation either exceeding or below a certain wavelength, e.g. bleed from the LED chip or undesirable short-wavelength emission from a phosphor. Examples of suitable filters include the Roscolux filters #10 (medium Yellow), #12 (Straw), #14 (Medium Straw), #15 (Deep Straw), #20 (medium Amber), #312 (Canary), #4590 (CalColor 90 Yellow), #22 (Deep Amber) and #19 (Fire). It will be clear to one skilled in the art that other yellow or red filters with similar transmission characteristics may be used instead, to achieve color-bin conformance.

### EXAMPLES

Various model systems using phosphor blends are listed in Table 1. A filter indicated, whenever present. The CIE color coordinates were determined using the emission spectra from 415 to 750 nm. All examples use near UV exitation with a maximum from about 350 nm to 410 nm.

TABLE 1

| Ex- | | | | | Composition |
|---|---|---|---|---|---|
| ample | x | y | Color | Filter | (by spectral weight) |
| 1 | 0.695 | 0.303 | Red | none | 50% MFG, balance |
| | | | | | K₂[Ti_{0.96}Mn_{0.04}F₆] |
| 2 | 0.699 | 0.296 | Red | none | 95% MFG, balance |
| | | | | | Gd_{0.95}Eu_{0.05}Al₃B₄O₁₂ |
| 3 | 0.690 | 0.301 | Red | none | 90% MFG, balance |
| | | | | | Gd_{0.95}Eu_{0.05}Al₃B₄O₁₂ |
| 4 | 0.547 | 0.446 | Yellow | none | 55% Gd_{0.95}Eu_{0.05}Al₃B₄O₁₂, |
| | | | | | balance |
| | | | | | Ca_{0.99}Ce_{0.01}Al_{0.99}Mg_{0.01}SiN₃ |
| 5 | 0.694 | 0.305 | Red | none | 80% Gd_{0.95}Eu_{0.05}Al₃B₄O₁₂, |
| | | | | | balance MFG |
| 6 | 0.542 | 0.448 | Yellow | Cal- | 100% HALO |
| | | | | Color | |
| | | | | 90 | |
| | | | | Yellow | |
| 7 | 0.543 | 0.448 | Yellow | Straw | 100% HALO |
| 8 | 0.548 | 0.448 | Yellow | Canary | 100% HALO |
| 9 | 0.556 | 0.439 | Yellow | Deep | 100% HALO |
| | | | | Straw | |
| 10 | 0.574 | 0.420 | Yellow | Medium | 100% HALO |
| | | | | Amber | |

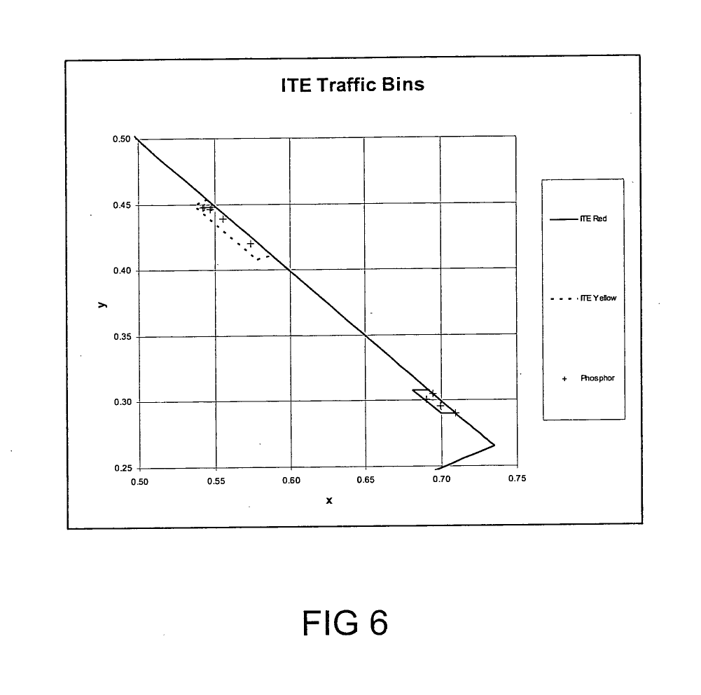

The color x, y coordinates of these examples in the 1931 CIE chromaticity diagram are shown in FIG. 6. As can be seen, these samples lie within the respective ITE color bins for red and yellow traffic lights.

The exemplary embodiment has been described with reference to the preferred embodiments. Obviously, modifications and alterations will occur to others upon reading and understanding the preceding detailed description. It is intended that the exemplary embodiment be construed as including all such modifications and alterations insofar as they come within the scope of the appended claims or the equivalents thereof.

What is claimed is:

1. A yellow emitting led illumination system comprising an InGaN semiconductor light emitter having a peak emission from 250 to 500 nm and a luminescent material, wherein said illumination system has an emission having CIE color coordinates located within an area of the CIE chromaticity diagram bounded by the following CIE color coordinates:
a) x=0.545 and y=0.454;
b) x=0.536 and y=0.449;
c) x=0.578 and y=0.408; and
d) x=0.588 and y=0.411.

2. An LED illumination system according to claim 1, wherein said luminescent material comprises one or more phosphor compositions selected from the group including: (Ca,Sr,Ba)₂Si₁₋ₐO₄₋₂ₐ:Eu²⁺ (wherein 0≦a≦0.2); (Mg,Ca,Sr,Ba,Zn)₅(PO₄)₃(F,Cl,Br,OH):Eu²⁺,Mn²⁺; (Mg,Ca,Sr,Ba,Zn)₂P₂O₇:Eu²⁺,Mn²⁺; Ca₃(SiO₄)Cl₂:Eu²⁺; (Y,Lu,Gd)_{2-b}Ca_{b}Si₄N_{6+b}:C_{1-b}:Ce³⁺ (wherein 0≦b≦1); garnet phosphors doped with Ce³⁺; Ca_{1-c}Ce_{c}Al_{1-c}Mg_{c}SiN₃ (wherein 0.001≦c≦0.2); Ca_{1-2d}Ce_{d}Li_{d}AlSiN₃(wherein 0.001≦d≦0.2); and (Lu,Ca,Li,Mg,Y)alpha-SiAION doped with Eu²⁺ and/or Ce³⁺.

3. An LED illumination system according to claim 1, wherein said system comprises a traffic signal indicator including a traffic signal housing and a traffic light lens.

4. An LED illumination system according to claim 1, further comprising:
a support on which the at semiconductor light emitter is disposed;
a cover disposed on the support over the semiconductor light emitter, the cover and the support cooperatively defining an interior volume containing the semiconductor light emitter; and
an encapsulant disposed in the interior volume and encapsulating the semiconductor light emitter.

5. An LED illumination system according to claim 4, wherein the luminescent material is deposited on an inside surface of the cover.

6. An LED illumination system according to claim 4, further comprising:
an optical coating disposed on a surface of the cover, the optical coating reflecting or absorbing light produced by the at least one light emitting die; and wherein said luminescent material is disposed in the interior volume, the optical coating substantially transmitting light produced by said luminescent material.

7. An LED illumination system according to claim 6, wherein said luminescent material is deposited on the optical coating.

8. An LED illumination system according to claim 4, wherein said luminescent material is dispersed in a portion of the encapsulant distal from the semiconductor light emitter and proximate to the cover.

9. An LED illumination system according to claim 4, wherein the cover includes a perimeter substantially hermetically sealed to the support.

10. An LED illumination system according to claim 1, wherein said system further includes a cutoff filter to cutoff radiation either exceeding or below a certain wavelength in order to bring the color point of the device inside the specified CIE color coordinates.

11. A red emitting LED illumination system comprising an InGaN semiconductor light emitter having a peak emission from 250 to 500 nm and a luminescent material, wherein said illumination system has an emission having CIE color coordinates located within an area of the CIE chromaticity diagram bounded by the following CIE color coordinates:
a) x=0.692 and y=0.308;
b) x=0.681 and y=0.308;
c) x=0.700 and y=0.290; and
d) x=0.710 and y=0.290.

12. An LED illumination system according to claim 11, wherein said luminescent material comprises one or more phosphor compositions selected from the group including:
a) 3.5MgO*0.5MgF₂*GeO₂:Mn⁴⁺;
b) (Mg,Ca,Sr,Ba,Zn)₄Si₂O₈:Eu²⁺,Mn²⁺;
c) nitride phosphors and sulfide phosphors selected from (Ca,Sr,Ba_{c})₂Si₅N₈:Eu; (Ca,Sr)S:Eu; CaSiN₂:Eu; (Ba,Ca)Si₇N₁₀:Eu; L_{g}MₕN_{(2/3)g+(4/3)h)}:R; or LⱼMₖOₗN_{(2/3)j+(4/3) k-(2/3)l)}:R (wherein L is at least one or more selected from the Group II Elements consisting of Mg, Ca, Sr, Ba and Zn, M is at least one or more selected from the Group IV Elements in which Si is essential among C, Si and Ge, and R is at least one or more selected from the rare earth elements in which Eu is essential among Y, La, Ce, Pr, Nd, Sm, Eu, Gd, Tb, Dy, Ho, Er and Lu.); (Ca₁₋ₘ₋ₙCeₘEuₙ)(Al₁₋ₘMgₘ)SiN₃ (wherein n>0); and/or (Ca_{1-o-p-q}LiₒCeₚEu_{q})Al₁₋ₒ₊ₚSi₁₊ₒ₋ₚN₃ (wherein q>0);
d) A₂₋ᵣEuᵣW₁₋ₛMoₛO₆, where A is selected from Y, Gd, Lu, La, and combinations thereof; and where 0.001≦r≦0.4, 0.001≦s≦1.0;
e) MᵤOᵥX, wherein M is selected from the group consisting of Sc, Y, La, a lanthanide, Bi, an alkali earth metal and mixtures thereof; X is a halogen; 1≦u≦3; and 1≦v≦4, and having a lanthanide doping level ranging from 0.001% to 40% by weight;
f) phosphate or borate phosphors doped with Eu³⁺ selected from: (Y,Gd,Lu,La)PO₄; (Y,Gd,Lu,La)P₃O₉; (Y,Gd,Lu,La)P₅O₄; (Sr,Ba,Ca)₃(Lu,Gd,Y,La)P₃O₁₂; Ca_{1.5}Ba_{1.5}(La,y,Gd,Lu)P₃O₁₂; (Y,La,Lu,Gd)BO₃; (Gd,Y,LuLa)B₃O₆; (La,Gd,Lu,Y)(Al,Ga)₃B₄O₁₂; (Y,Gd,Lu,La)MgB₅O₁₀; (Sr,Ca,Ba)(Lu,Gd,Y,La)B₇O₁₃; and/or Ca_{0.5}Ba_{0.5}LaB₇O₁₃; and
g) A₂[MF₆]:Mn⁴⁺, where A=Li, Na, K, Rb or Cs and M=Ge, Si, Sn, Ti or Zr.

13. An LED illumination system according to claim 11, wherein said system comprises a traffic signal indicator including a traffic signal housing and a traffic light lens.

14. An LED illumination system according to claim 13, further comprising:
a support on which the at semiconductor light emitter is disposed;
a cover disposed on the support over the semiconductor light emitter, the cover and the support cooperatively defining an interior volume containing the semiconductor light emitter; and
an encapsulant disposed in the interior volume and encapsulating the semiconductor light emitter.

15. An LED illumination system according to claim 14, wherein the luminescent material is deposited on an inside surface of the cover.

16. An LED illumination system according to claim 14, further comprising:
an optical coating disposed on a surface of the cover, the optical coating reflecting or absorbing light produced by the at least one light emitting die; and wherein said luminescent material is disposed in the interior volume, the optical coating substantially transmitting light produced by said luminescent material.

17. An LED illumination system according to claim 16, wherein said luminescent material is deposited on the optical coating.

18. An LED illumination system according to claim 14, wherein said luminescent material is dispersed in a portion of the encapsulant distal from the semiconductor light emitter and proximate to the cover.

19. An LED illumination system according to claim 14, wherein the cover includes a perimeter substantially hermetically sealed to the support.

20. An LED illumination system according to claim 11, wherein said system further includes a cutoff filter to cutoff radiation either exceeding or below a certain wavelength in order to bring the color point of the device inside the specified CIE color coordinates.
